(19) United States
(12) Patent Application Publication
(10) Pub. No.: US 2017/0062326 A1
(43) Pub. Date: Mar. 2, 2017

(54) LINE STRUCTURE FOR MATCHING SIGNAL LINES OF SEMICONDUCTOR DEVICE

(71) Applicant: SK hynix Inc., Gyeonggi-do (KR)

(72) Inventor: Su Hyun KIM, Gyeonggi-do (KR)

(21) Appl. No.: 15/016,976

(22) Filed: Feb. 5, 2016

(30) Foreign Application Priority Data
Sep. 1, 2015 (KR) 10-2015-0123829

(51) Int. Cl. H01L 23/528; H01L 23/50

(52) U.S. Cl. CPC H01L 23/528; H01L 23/50

(57) ABSTRACT

A line structure for matching of signal lines of a semiconductor device is disclosed. The line structure for matching of signal lines of a semiconductor device includes: a first signal line extended in a first direction; a second signal line extended in a second direction, and coupled to the first signal line; and a load-adjusting line spaced apart from the second signal line by a predetermined distance, and coupled to the first signal line.

### CROSS-REFERENCE TO RELATED APPLICATION

The present disclosure claims priority of Korean patent application No. 10-2015-0123829 filed on Sep. 1, 2015, the disclosure of which is incorporated hereby in its entirety by reference.

### BACKGROUND OF THE INVENTION

Embodiments of the present disclosure relate generally to a line structure for a semiconductor device and more particularly to a line structure capable of minimizing the number of signal lines performing the same functionality, and synchronizing the signal lines to have the same signal timing.

As processing speed of a semiconductor device increases, the importance of synchronizing signals performing the same function to achieve the same signal timing also increases Specifically, for products employing several input/output (I/O) signals, such as high bandwidth memories (HBMs), it may be difficult synchronizing each delay and driver memory cell.

Typically, for a plurality of signal lines to have the same signal timing, a load matching operation is carried out so that lengths of signal lines performing the same function may be adjusted to become identical.

FIG. 1 is a conceptual diagram illustrating a conventional load matching method for signal lines.

In FIG. 1, a transmission line may include metal lines M1, M2 configured to transmit specific signals (I/O data) performing the same function. The metal lines M1, M2 may be disposed between a source and a target. The transmission line may include first signal lines M1 extending in a first direction; and second signal lines M2 extending in a second direction, wherein each second signal line is coupled to a corresponding first signal line through a contact CONT.

Typically, the lengths of short-loading signal lines are extended on the basis of the longest line among signal lines performing the same function. As shown in FIG. 1, the extended part is formed in a bent (or curved) shape obtained when the signal lines are bent toward regions of other lines. A connection path for signal transmission between a source (acting as a signal transmitter) and a target (acting as a signal receiver) is formed in a bent or curved shape, so that the connection path can be lengthened.

However, when the signal lines are bent or curved to extend the connection path as described above, a single signal line may occupy two or more line regions as shown in FIG. 1. Hence, it may not be possible to form other signal lines on regions occupied by the bent or curved lines.

Therefore, a conventional method for extending the connection path by bending the signal lines to implement load matching may have a disadvantage in that several regions that could be used for line formation may be unnecessarily used or wasted.

The above issue becomes more problematic as the number of signal lines requiring load matching increases, especially in products such as high bandwidth memories (HBMs).

### BRIEF SUMMARY OF THE INVENTION

Various embodiments of the present disclosure are directed to providing a line structure for load matching of signal lines performing the same function of a semiconductor device, thereby preventing one or more problems due to limitations and disadvantages of the prior art.

An embodiment of the present disclosure relates to a technology for minimizing the number of signal lines configured to transmit the same signals by improving a layout structure of the signal lines, and synchronizing the signal lines such that they can have the same signal timing.

In accordance with an aspect of the present disclosure, a line structure for matching of signal lines of a semiconductor device includes: a first signal line extended in a first direction; a second signal line extended in a second direction, and coupled to the first signal line; and a load-adjusting line spaced apart from the second signal line by a preset distance, and coupled to the first signal line.

It is to be understood that both the foregoing general description and the following detailed description of embodiments are exemplary and explanatory.

### BRIEF DESCRIPTION OF THE DRAWINGS

FIG. 1 is a schematic diagram illustrating a layout structure of metal lines for load matching of signal lines according to the related art.

FIG. 2 is a schematic diagram illustrating a layout structure of metal lines for load matching of signal lines, according to an embodiment of the present disclosure.

FIG. 3 is a schematic diagram illustrating a layout structure of metal lines for load matching of signal lines, according to another embodiment of the present disclosure.

FIG. 4 is a schematic diagram illustrating a layout structure of metal lines for load matching of signal lines, according to yet another embodiment of the present disclosure.

### DESCRIPTION OF EMBODIMENTS

Reference will now be made In detail to various embodiments of the invention in conjunction with the accompanying drawings. Wherever possible, the same reference numbers will be used throughout the drawings to refer to the same or like parts. In the following description, a detailed description of related known configurations or functions incorporated herein may be omitted when it may obscure the subject matter and/or may be repetitious.

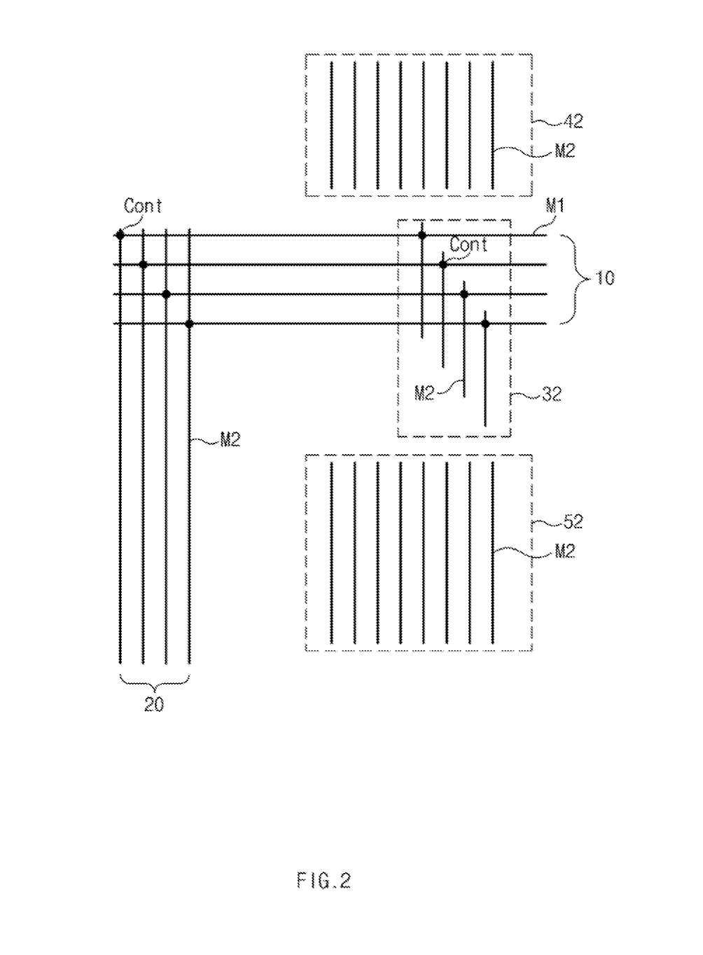

Referring to FIG. 2 a layout structure of metal lines for load matching of signal lines is provided, according to an embodiment of the present disclosure. The signal lines may be performing the same function. Load matching may include adjusting the length of signal lines performing the same function to match the length of a reference signal line. The length of a signal line may be adjusted by connecting one or more load-adjusting lines to the signal line.

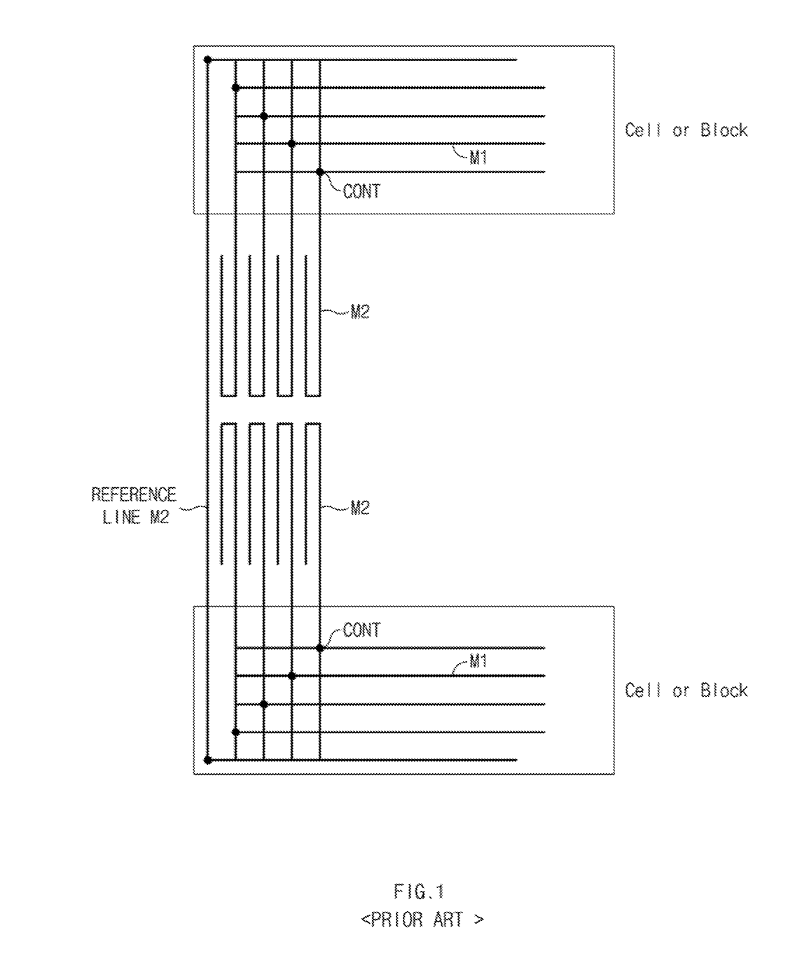

Accordingly, with a line structure according to an embodiment of the present disclosure, a connection path through which a signal is actually transmitted between a source (i.e., a signal transmitter) and a target (i.e., a signal receiver) may not be extended by bending the connection path as shown in FIG. 1, but by adding redundant lines unused for such signal transmission to the connection path, so that the total length of the corresponding lines may become identical to a length of a reference line.

For example, load-adjusting lines for matching only loading of the corresponding lines irrespective of signal transmission may be coupled to the connection path (i.e., transmission line) for such signal transmission. A detailed description thereof will now be provided with reference to FIG. 2.

For example in the embodiment of FIG. 2 a transmission line comprising metal lines M1, M2 is shown The metal lines M1, M2, may be configured to transmit specific signals (I/O data) performing the same function. The metal lines M1, M2 may be disposed between a source and a target. The transmission line may include first signal lines 10 extending in a first direction and second signal lines 20 extending in a second direction. Each of the second signal lines 20 may be coupled to a corresponding first signal line 10 through a contact (Cont). In the embodiment shown, for example the first signal lines 10 may be formed of metal lines M1, whereas the second signal lines 20 may be formed of metal lines M2.

Load-adjusting lines 32 for load matching transmission line to a reference line may be coupled to the first signal lines 10 of the transmission line, respectively, through a corresponding contact (Cont). For example, the load-adjusting lines 32 may be in the same direction as the second signal lines 20. The load-adjusting lines 32 may include metal lines formed at the same level (layer) as the second signal lines 20. For example, the load-adjusting lines 32 may include metal lines M2 patterned at the same time with the second signal lines 20.

Specifically, according to an embodiment of the present disclosure, the load-adjusting lines 32 may be patterned or formed in regions where metal lines M2 having different functions from the transmission lines (10, 20) are not formed. For example, the load-adjusting lines 32 may be formed in the remaining regions outside of the metal line (M2) region, where metal lines (42, 52) (e.g. other signal transmission lines, power lines, etc.) needed to operate a semiconductor device may not be formed. Therefore, an embodiment of the disclosure, overcomes the problem that a region in which other lines (42, 52) may be formed to implement load matching of the transmission lines 10, 20 may be unnecessarily wasted or used.

For example the length of each load-adjusting line 32 may be adjusted according to the length of a reference line. For example, the length of the load-adjusting lines 32 may be determined in a manner that the sum of the lengths of transmission lines and the lengths of corresponding load-adjusting lines 32 may be identical to the length of a reference line.

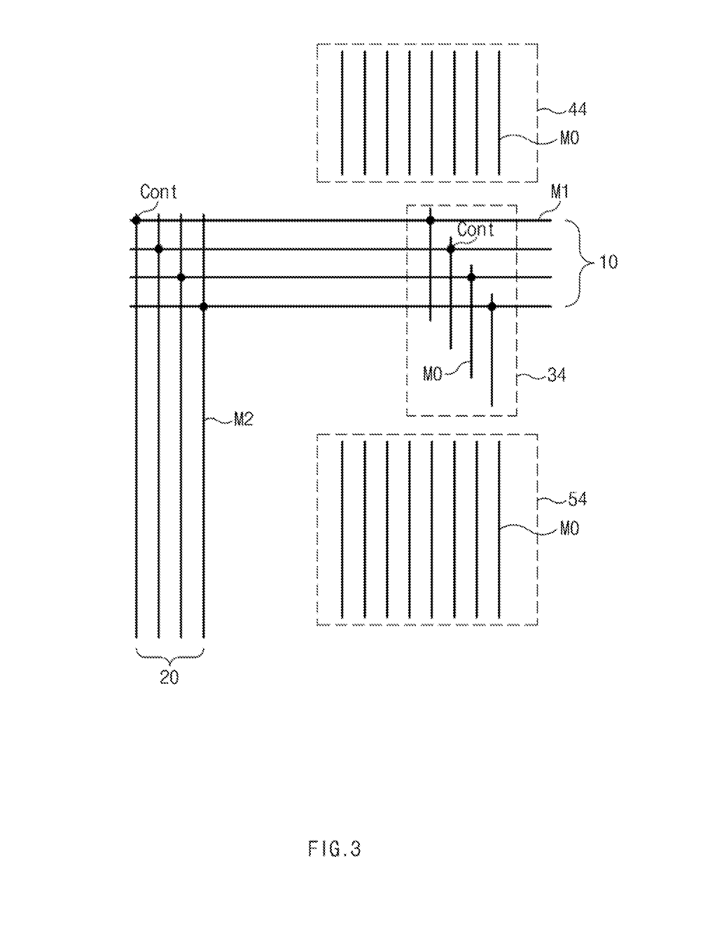

FIG. 3 is a schematic diagram illustrating a layout structure of metal lines for load matching, according to another embodiment of the present disclosure.

In the embodiment of FIG. 2 each load-adjusting line 32 may be formed of a metal line having the same level as the second signal line 20. For example, FIG. 2 exemplarily shows that each load-adjusting line 32 may be formed of a metal line M2 corresponding to a higher level than the first signal line 10.

In contrast, a load-adjusting line 34 of FIG. 3 is formed of a metal line M0 corresponding to a lower level than a first signal line 10.

For example, if necessary, the load-adjusting lines (34) may also be replaced with metal lines disposed at upper or lower parts of the first signal line 10 without departing from the scope or spirit of the present disclosure.

In addition, although FIGS. 2 and 3 exemplarily show that the load-adjusting lines (32 34) may be formed in the metal line M2 or the metal line M0 for convenience of description, the load-adjusting lines (32, 34) may also be formed in both of the metal line M2 and the metal line M0 as necessary. For example, when we assume that a sufficient-sized space in which all load-adjusting lines can be formed is not available in any one of the metal line M2 and the metal line M0, the load-adjusting lines may also be distributed to two metal lines as necessary.

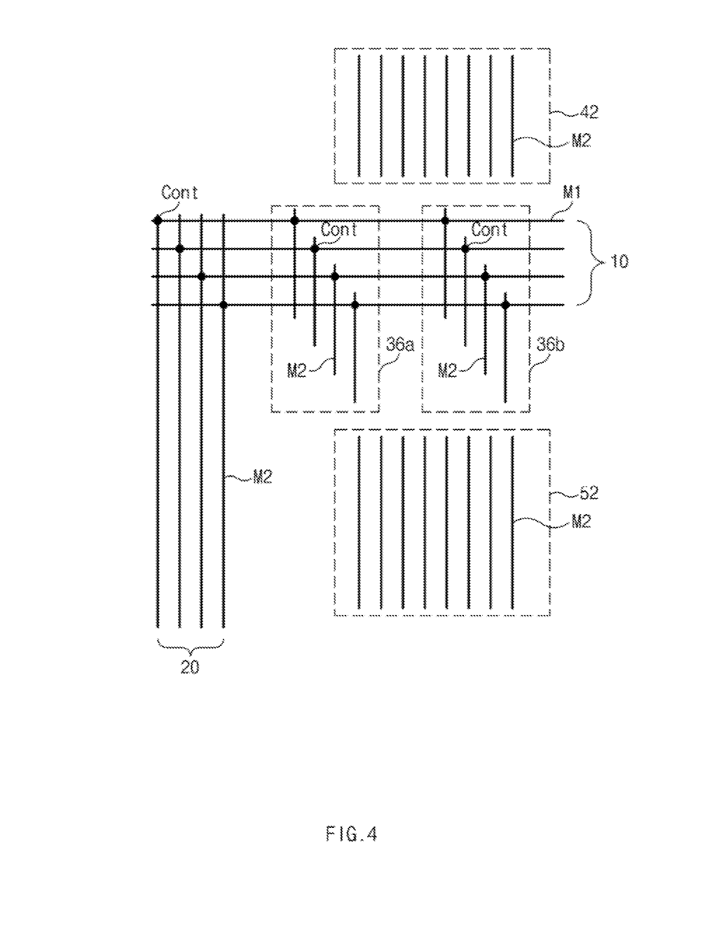

FIG. 4 is a schematic diagram illustrating a layout structure for load matching of metal lines, according to yet another embodiment of the present disclosure.

FIGS. 2 and 3 exemplarily show that one load-adjusting line may be coupled to each transmission line.

In contrast, the embodiment of FIG. 4 exemplarily chows that several load-adjusting lines (36a, 36b) may be coupled to respective transmission lines.

For example, if it is impossible to form a desired length using a single line, the corresponding load-adjusting line may be divided into a plurality of lines. In this case, the divided load-adjusting lines (36a, 36b) may be formed of same-level metal lines (M2 or M0), or may be formed of different-level metal lines (M2 and M0).

As is apparent from the above description, various embodiments of the present disclosure may minimize the number of signal lines configured to transmit the same signals, and/or may synchronize the signal lines so that they can have the same signal timing.

Those skilled in the art will appreciate that various embodiments of the present disclosure may be carried out in other ways than those set forth herein without departing from the spirit and essential characteristics of these embodiments. The above embodiments are therefore to be construed in all aspects as illustrative and not restrictive.

Various alternatives and equivalents are possible. The invention is not limited by any particular type of deposition, etching polishing, and/or patterning steps. Nor is the invention limited to any specific type of semiconductor device. For example, the present disclosure may be implemented in a dynamic random access memory (DRAM) device or a nonvolatile memory device. Other additions, subtractions, or modifications will become obvious to those skilled in the art to which the invention pertains in view of the present disclosure without departing from the spirit or scope of the invention as defined by the appended claims.

What is claimed is:

1. A line structure for matching of signal lines of a semiconductor device comprising:
a first signal line extended in a first direction;
a second signal line extended in a second direction, and coupled to the first signal line; and
a load-adjusting line spaced apart from the second signal line by a preset distance, and coupled to the first signal line.

2. The line structure according to claim 1, wherein each of the first, second and load-adjusting lines includes a metal line.

3. The line structure according to claim 1, wherein the second signal line is coupled to the first signal line through a first contact.

4. The line structure according to claim 3, wherein the load-adjusting line is coupled to the first signal line through a second contact.

5. The line structure according to claim 4 wherein the load-adjusting line includes a metal line having the same level as the second signal line.

6. The line structure according to claim 4, wherein the load-adjusting line includes a metal line having a different level from the second signal line.

7. The line structure according to claim 4, wherein the load-adjusting line includes a first metal line having the same level as the second signal line, and a second metal line having a different level from the second signal line.

8. The line structure according to claim 1, wherein the load-adjusting line is extended in the second direction.
